(19) United States
(12) Patent Application Publication
(10) Pub. No.: US 2023/0352639 A1
(43) Pub. Date: Nov. 2, 2023

(54) DISPLAY DEVICE

(71) Applicant: SAMSUNG DISPLAY CO., LTD., Yongin-si, Gyeonggi-do (KR)

(72) Inventors: Jung Hwan YI, Yongin-si, Gyeonggi-do (KR); Jin Taek KIM, Yongin-si, Gyeonggi-do (KR); Yong Sub SHIM, Yongin-si, Gyeonggi-do (KR); Seung Min LEE, Yongin-si, Gyeonggi-do (KR); Hee Keun LEE, Yongin-si, Gyeonggi-do (KR); Baek Hyeon LIM, Yongin-si, Gyeonggi-do (KR); Kyung Tae CHAE, Yongin-si, Gyeonggi-do (KR); Hae Ju YUN, Yongin-si, Gyeonggi-do (KR); Seung Jin CHU, Yongin-si, Gyeonggi-do (KR)

(73) Assignee: SAMSUNG DISPLAY CO., LTD., Yongin-si, Gyeonggi-do (KR)

(21) Appl. No.: 18/018,934

(22) PCT Filed: Jul. 8, 2021
(86) PCT No.: PCT/KR2021/008731

§ 371 Date: Jan. 31, 2023

(30) Foreign Application Priority Data
Jul. 31, 2020 (KR) 10-2020-0096224

(51) Int. Cl. H01L 33/24; H01L 25/075; H01L 33/60; H01L 33/38; H01L 33/62

(52) U.S. Cl. CPC H01L 33/60; H01L 25/0753; H01L 33/24; H01L 33/38; H01L 33/62

(57) ABSTRACT

A display device includes a substrate including a plurality of pixels, a first electrode and a second electrode disposed on the substrate and spaced apart from each other, an insulating reflective layer disposed on the first electrode and the second electrode, and a plurality of light emitting elements disposed between the first electrode and the second electrode and electrically connected to the first electrode and the second electrode, wherein the insulating reflective layer includes a plurality of first layers and the plurality of second layers having different refractive indexes, and the the plurality of first layers and the the plurality of second layers are alternately stacked with each other.

### CROSS-REFERENCE TO RELATED APPLICATION(S)

This application is a national entry of International Application No. PCT/KR2021/008731, filed on Jul. 8, 2021, which claims under 35 U.S.C. §§ 119(a) and 365(b) priority to and benefits of Korean Patent Application No. 10-2020-0096224, filed on Jul. 31, 2020, in the Korean Intellectual Property Office (KIPO), the entire content of which are incorporated herein by reference.

### BACKGROUND

### 1. Technical Field

Embodiments relate to a display device.

### 2. Description of the Related Art

Recently, interest in an information display is increasing. Accordingly, research and development on a display device are continuously being conducted.

### SUMMARY

Embodiments provide a display device capable of improving light output efficiency.

Embodiments are not limited to those set forth herein. The above and other embodiments will become more apparent to one of ordinary skill in the art to which the disclosure pertains by referencing the detailed description of the disclosure given below.

In an embodiment, a display device may include: a substrate including a plurality of pixels, a first electrode and a second electrode disposed on the substrate and spaced apart from each other, an insulating reflective layer disposed on the first electrode and the second electrode, and a plurality of light emitting elements disposed between the first electrode and the second electrode and electrically connected to the first electrode and the second electrode, wherein the insulating reflective layer may include a plurality of first layers and a plurality of second layers having different refractive indexes, and the plurality of first layers and the plurality of second layers are alternately stacked with each other.

The insulating reflective layer may overlap end portions of the plurality of light emitting elements.

A refractive index of the plurality of first layers of the insulating reflective layer may be smaller than a refractive index of the plurality of second layers of the insulating reflective layer.

A thickness of the plurality of first layers of the insulating reflective layer may be greater than a thickness of the plurality of second layers of the insulating reflective layer.

A thickness of the insulating reflective layer may be about 4,000 angstroms or more.

The insulating reflective layer may include four or more pairs of the plurality of first layers and the plurality of second layers.

Each of the plurality of first layers of the insulating reflective layer may include a silicon oxide, and each of the plurality of second layers of the insulating reflective layer may include a silicon nitride.

Each of the plurality of first layers of the insulating reflective layer may include a silicon oxide, and each of the plurality of second layers of the insulating reflective layer may include a titanium oxide.

The display device may further include a first contact electrode contacting the first electrode and an end portion of each of the plurality of light emitting elements; and a second contact electrode contacting the second electrode and another end portion of each of the plurality of light emitting elements.

The insulating reflective layer may be disposed between the first electrode and the first contact electrode.

A surface of the insulating reflective layer may contact the first electrode, and another surface of the insulating reflective layer may contact the first contact electrode.

The insulating reflective layer may include an opening that partially exposes the first electrode.

The first contact electrode may contact the first electrode through the opening of the insulating reflective layer.

Aspects of other embodiments are included in the detailed description and drawings.

In an amendment, a display device may include: a substrate including a plurality of pixels; a first electrode and a second electrode disposed on the substrate and spaced apart from each other; an insulating reflective layer disposed on the first electrode and the second electrode; and a plurality of light emitting elements disposed on the insulating reflective layer and electrically connected to the first electrode and the second electrode, wherein the insulating reflective layer may include a first insulating reflective portion having a first thickness and a second insulating reflective portion having a second thickness smaller than the first thickness.

The first insulating reflective portion may overlap a center portion of each of the plurality of light emitting elements, and the second insulating reflective portion may overlap an end portion of each of the plurality of light emitting elements.

The first insulating reflective portion may be adjacent to a side of the first electrode and a side of the second electrode.

The insulating reflective layer may include a plurality of first layers and a plurality of second layers having different refractive indexes, and the plurality of first layers and the plurality of second layers may be alternately stacked with each other.

A refractive index of the plurality of first layers of the insulating reflective layer may be smaller than a refractive index of the plurality of second layers of the insulating reflective layer.

A thickness of each of the plurality of first layers of the insulating reflective layer may be greater than a thickness of each of the plurality of second layers of the insulating reflective layer.

The insulating reflective layer may include four or more pairs of the plurality of first layers and the plurality of second layers.

According to embodiments, since an insulating reflective layer is disposed under a light emitting element, light emitted to a lower portion of the light emitting element may be reflected by the insulating reflective layer to be emitted in a front direction of a display panel. Accordingly, since an amount of light lost to a lower portion of the display panel may be minimized, the light output efficiency may be improved.

Effects of embodiments are not limited by what is illustrated in the above, and more various effects are included in the specification.

### BRIEF DESCRIPTION OF THE DRAWINGS

FIG. 1 and FIG. 2 illustrate a schematic perspective view and a schematic cross-sectional view of a light emitting element according to an embodiment, respectively.

FIG. 3 and FIG. 4 illustrate a schematic perspective view and a cross-sectional view of a light emitting element according to an embodiment, respectively.

FIG. 5 illustrates a schematic top plan view of a display device according to an embodiment.

FIGS. 6 to 10 illustrate circuit diagrams of a pixel according to an embodiment.

FIG. 11 and FIG. 12 illustrate schematic top plan views of a pixel according to an embodiment.

FIGS. 13 to 15 illustrate schematic cross-sectional views of a pixel according to an embodiment.

FIG. 16 illustrates a schematic cross-sectional view of an insulating reflective layer according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Hereinafter, embodiments will be described in detail with reference to the accompanying drawings.

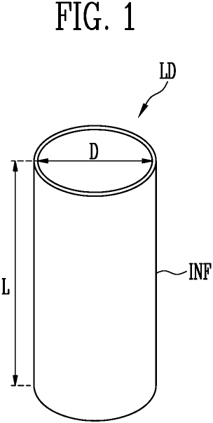

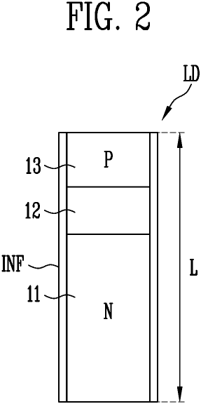

FIG. 1 and FIG. 2 illustrate a schematic perspective view and a schematic cross-sectional view of a light emitting element according to an embodiment, respectively. In FIG. 1 and FIG. 2, a cylindrical rod-shaped light emitting element LD is illustrated, but a type and/or shape of the light emitting element LD is not limited thereto.

Referring to FIG. 1 and FIG. 2, the light emitting element LD may include a first semiconductor layer 11 and a second semiconductor layer 13, and an active layer 12 disposed between the first and second semiconductor layers 11 and 13. For example, the light emitting element LD may be formed in a stacked body in which the first semiconductor layer 11, the active layer 12 and the second semiconductor layer 13 are sequentially stacked in a direction.

In some embodiments, the light emitting element LD may have a rod shape extending in a direction. The light emitting element LD may have a first end portion and a second end portion in a direction.

In some embodiments, one of the first and second semiconductor layers 11 and 13 may be disposed at the first end portion of the light emitting element LD, and another one of the first and second semiconductor layers 11 and 13 may be disposed at the second end portion of the light emitting element LD.

In some embodiments, the light emitting element LD may be a rod-shaped light emitting diode manufactured in a rod shape. For example, the rod shape may include a rod-like shape or a bar-like shape, of which a longitudinal direction is longer than a width direction thereof (e.g., a shape having an aspect ratio greater than 1), such as a cylinder or polygonal column, and a shape of a cross section thereof is not limited. For example, the length L of the light emitting element LD may be larger than a diameter D thereof (or a width of a lateral cross-section thereof).

In some embodiments, the light emitting element LD may have a size as small as a nanometer scale to a micrometer scale, for example, a diameter D and/or a length L in a range of about 100 nm to about 10 um. However, the size of the light emitting element LD is not limited thereto. For example, the size of the light emitting element LD may be variously changed according to various devices including a light emitting device including the light emitting element LD as a light source, for example, a display device.

The first semiconductor layer 11 may include at least one n-type semiconductor material. For example, the first semiconductor layer 11 may include a semiconductor material of one of InAlGaN, GaN, AlGaN, InGaN, AlN, and InN, and may include a n-type semiconductor material doped with a first conductive dopant such as Si, Ge, Sn, or the like.

The active layer 12 may be disposed on the first semiconductor layer 11, and may have a single quantum well structure or a multi-quantum well structure. In an embodiment, a clad layer doped with a conductive dopant may be formed at an upper portion and/or a lower portion of the active layer 12. For example, the clad layer may be formed as an AlGaN layer or an InAlGaN layer. In some embodiments, a material such as AlGaN and AlIn—GaN may be used to form the active layer 12, and various materials may form the active layer 12. The active layer 12 may be disposed between the first semiconductor layer 11 and the second semiconductor layer 13 to be described below.

In case that a voltage of a threshold voltage or more is applied to respective ends of the light emitting element LD, the light emitting element LD may emit light in case that electron-hole pairs are combined in the active layer 12. By controlling the light emitted from the light emitting element LD, the light emitting element LD may be used as a light source for various light emitting devices in addition to pixels of a display device.

The second semiconductor layer 13 may be disposed on the active layer 12, and may include a semiconductor material of a type different from that of the first semiconductor layer 11. For example, the second semiconductor layer 13 may include at least one p-type semiconductor material. For example, the second semiconductor layer 13 may include at least one semiconductor material of InAlGaN, GaN, AlGaN, InGaN, AlN, and InN, and may include a p-type semiconductor material doped with a second conductive dopant such as Mg. However, embodiments are not limited thereto, and the second semiconductor layer 13 may be formed of various materials.

In some embodiments, the first length of the first semiconductor layer 11 may be longer than the second length of the second semiconductor layer 13.

In some embodiments, the light emitting element LD may further include an insulating film INF disposed on a surface thereof. The insulating film INF may be formed on the surface of the light emitting element LD so as to surround at least an outer circumferential surface of the active layer 12, and may further surround an area of the first and second semiconductor layers 11 and 13.

In some embodiments, the insulating film INF may expose respective end portions of the light emitting element LD having different polarities. For example, the insulating film INF may not cover an end portion of each of the first and second semiconductor layers 11 and 13 at end portions (e.g., opposite end portions) of the light emitting element LD in the length direction, for example, two flat surfaces (e.g.,, upper and lower surfaces) of the circular cylinder, but may expose it. In some embodiments, the insulating film INF may expose end portions (e.g., opposite end portions) of the light emitting element LD having different polarities and side portions of the semiconductor layers 11 and 13 adjacent to the end portions (e.g., opposite end portions).

In some embodiments, the insulating film INF may be formed as a single layer or a multilayer (for example, a double layer made of an aluminum oxide (AlOₓ) and a silicon oxide (SiOₓ)) by including at least one insulating material of a silicon oxide (SiOₓ), a silicon nitride (SiNₓ), an aluminum oxide (AlOₓ), and a titanium oxide (TiOₓ), but embodiments are not limited thereto. In some embodiments, the insulating film INF may be omitted.

In an embodiment, the light emitting element LD may further include an additional component in addition to the first semiconductor layer 11, the active layer 12, the second semiconductor layer 13 and/or the insulating film INF. For example, the light emitting element LD may additionally include one or more of a phosphor layer, an active layer, a semiconductor layer, and/or an electrode layer disposed on an end side of the first semiconductor layer 11, the active layer 12, and/or the second semiconductor layer 13.

In some embodiments, the light emitting element LD may further include an ohmic contact electrode or a Schottky contact electrode disposed on the semiconductor layers 11 and 13. The contact electrode may be disposed on an end portion of the first semiconductor layer 11 and/or an end portion of the second semiconductor layer 13. For example, a third semiconductor layer and a fourth semiconductor layer that are respectively disposed between the semiconductor layers 11 and 13 and the active layer 12 may be further included.

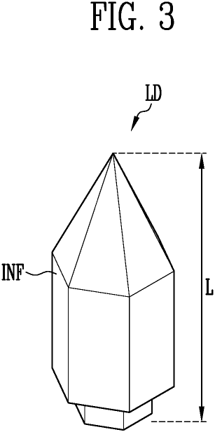

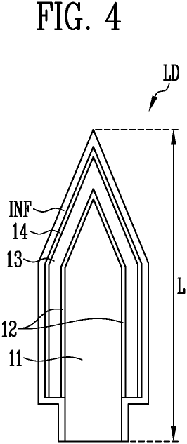

FIG. 3 and FIG. 4 illustrate a schematic perspective view and a schematic cross-sectional view of a light emitting element according to an embodiment, respectively.

Referring to FIG. 3 and FIG. 4, the light emitting element LD according to an embodiment may include a first semiconductor layer 11 and a second semiconductor layer 13, and an active layer 12 disposed between the first and second semiconductor layers 11 and 13. In some embodiments, the first semiconductor layer 11 may be disposed in a central area of the light emitting element LD, and the active layer 12 may be disposed on the surface of the first semiconductor layer 11 to surround at least a portion of the first semiconductor layer 11. For example, the second semiconductor layer 13 may be disposed on a surface of the active layer 12 to surround at least a portion of the active layer 12.

For example, the light emitting element LD may further include an electrode layer 14 and/or an insulating film INF, surrounding at least a portion of the second semiconductor layer 13. For example, the light emitting element LD may include the electrode layer 14 disposed on a surface of the second semiconductor layer 13 so as to surround an area of the second semiconductor layer 13, and the insulating film INF disposed on a surface of the electrode layer 14 so as to surround at least a portion of the electrode layer 14. For example, the light emitting element LD may be implemented to have a core-shell structure including the first semiconductor layer 11, the active layer 12, the second semiconductor layer 13, the electrode layer 14, and the insulating film INF sequentially disposed from a center portion to an outer side, and the electrode layer 14 and/or insulating film INF may be omitted in some embodiments.

In an embodiment, the light emitting element LD may be formed in a polygonal horn shape extending in a direction. For example, at least a portion of the light emitting element LD may have a hexagonal horn shape. However, embodiments are not limited thereto, and the shape of the light emitting element LD may be variously changed.

In an embodiment, end portions (e.g., opposite end portions)of the first semiconductor layer 11 may have a protruding shape in a direction of the length L of the light emitting element LD. The protruding shapes of end portions (e.g., opposite end portions) of the first semiconductor layer 11 may be different from each other. For example, an end portion at an upper side of end portions (e.g., opposite end portions) of the first semiconductor layer 11 may have a horn shape, a pyramid shape, or a cone shape with an apex (or vertex). For example, the end portion at the upper side of the first semiconductor layer 11 may be narrowed as moving toward the apex (or vertex). For example, another end portion at a lower side of the end portions of the first semiconductor layer 11 may have a polygonal column shape having a constant width, but embodiments are not limited thereto. In another example, the first semiconductor layer 11 may have a cross section of a polygonal shape or a step shape, which gradually decreases in width as it goes downward. The shapes of the end portions of the first semiconductor layer 11 may be variously changed according to embodiments, and thus, embodiments are not limited to the above-described embodiment.

In some embodiments, the first semiconductor layer 11 may be positioned at a core of the light emitting element LD, e.g., at a center (or central area). For example, the light emitting element LD may have a shape corresponding to a shape of the first semiconductor layer 11. In case that the first semiconductor layer 11 has a hexagonal horn shape, the light emitting element LD may have a hexagonal horn shape.

The following embodiments will be described as an example to which the light emitting element LD shown in FIG. 1 and FIG. 2 is applied, but the light emitting elements including the light emitting element LD shown in FIG. 3 and FIG. 4 to embodiments may be modified in various types.

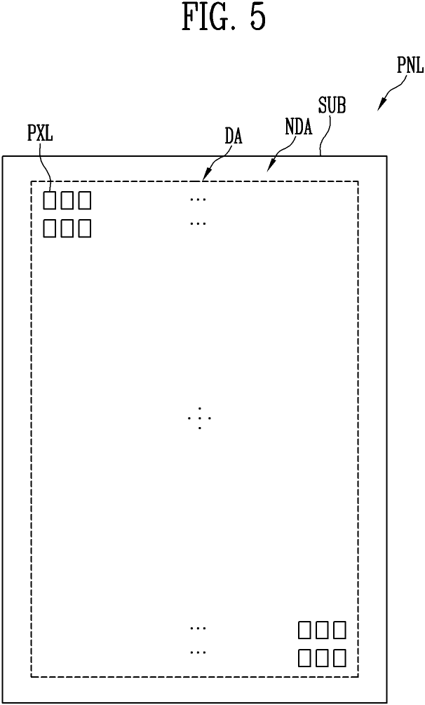

FIG. 5 illustrates a schematic top plan view of a display device according to an embodiment. FIG. 5 illustrates a display device, which is an example of a device including the above-described light emitting element LD as a light source, e.g., a display panel PNL formed in the display device. Referring to FIG. 5, the display panel PNL may include a substrate SUB and pixels PXL formed on the substrate SUB. For example, the display panel PNL and the substrate SUB may include a display area DA in which an image is displayed and a non-display area NDA excluding the display area DA. In some embodiments, the display area DA may be disposed in a central area of the display panel PNL, and the non-display area NDA may be disposed along an edge of the display panel PNL so as to surround the display area DA. However, embodiments are not limited thereto, and the positions of the display area DA and the non-display area NDA may be changed or modified.

The substrate SUB may be a base member of the display panel PNL. For example, the substrate SUB may be a base member of a lower panel (for example, a lower panel of the display panel PNL).

In some embodiments, the substrate SUB may be a rigid substrate or a flexible substrate, and its material or physical properties are not limited. For example, the substrate SUB may be a rigid substrate made of glass or tempered glass, or a flexible substrate made of a thin film made of plastic or metal. For example, the substrate SUB may be a transparent substrate, but embodiments are not limited thereto. For example, the substrate SUB may be a translucent substrate, an opaque substrate, or a reflective substrate.

An area on the substrate SUB may be formed as the display area DA in which the pixels PXL is disposed, and the remaining area may be formed as the non-display area NDA. For example, the substrate SUB may include the display area DA including pixel areas in which the pixels PXL are formed, and the non-display area NDA disposed outside the display area DA. In the non-display area NDA, various wires connected to the pixels PXL of the display area DA and/or internal circuit parts may be disposed.

The pixels PXL may include at least one light emitting element LD driven by corresponding scan and data signals, for example, at least one light emitting diode according to one of the embodiments of FIG. 1 to FIG. 4. For example, each of the pixels PXL may include light emitting diodes having a size as small as a nanometer scale to a micrometer scale and connected to each other in parallel or in series. Rod-shaped light emitting diodes may form a light source of the pixels PXL.

Although FIG. 5 illustrates the embodiment in which the pixels PXL are arranged in a stripe form in the display area DA, embodiments are not limited thereto. For example, the pixels PXL may be disposed in various pixel arrangement shapes, such as a Pentile^{®} shape.

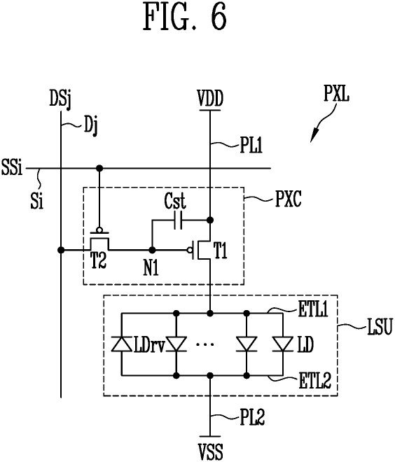

FIG. 6 to FIG. 10 illustrate circuit diagrams of a pixel according to an embodiment.

FIG. 6 to FIG. 10 illustrate that embodiments of a pixel PXL are applied to an active display device. However, the types of the pixel PXL and the display device to which the embodiment may be applied are not limited thereto.

First, referring to FIG. 6, the pixel PXL may include a light source unit LSU for generating light of a luminance corresponding to a data signal. For example, the pixel PXL may further selectively include a pixel circuit PXC for driving the light source unit LSU.

The light source unit LSU may include at least one light emitting element LD connected between a first power source VDD and a second power source VSS, for example, light emitting elements LD. For example, the light source unit LSU may include a first electrode ETL1 (referred to as a “first pixel electrode” or “first alignment electrode”) connected to the first power source VDD via the pixel circuit PXC and a first power line PL1, a second electrode ETL2 (referred to as a “second pixel electrode” or “second alignment electrode”) connected to the second power source VSS through a second power line PL2, and light emitting elements LD connected in parallel in the same direction between the first and second electrodes ETL1 and ETL2. In an embodiment, the first electrode ETL1 may be an anode electrode, and the second electrode ETL2 may be a cathode electrode.

Each of the light emitting elements LD may include a first end portion (for example, a P-type end portion) connected to the first power source VDD through the first electrode ETL1 and/or the pixel circuit PXC, and a second end portion (for example, an N-type end portion) connected to the second power source VSS through the second electrode ETL2. For example, the light emitting elements LD may be connected in parallel in a forward-bias direction between the first and second electrodes ETL1 and ETL2. Respective light emitting elements LD connected in the forward-bias direction between the first power source VDD and the second power source VSS may form respective effective light sources, and these effective light sources may be combined to form the light source unit LSU of the pixel PXL.

In some embodiments, the first and second power sources VDD and VSS may have different potentials so that the light emitting elements LD may emit light. For example, the first power source VDD may be set as a high potential power source, and the second power source VSS may be set as a low potential power source. For example, a potential difference between the first and second power source sources VDD and VSS may be set to be equal to or higher than a threshold voltage of the light emitting elements LD during at least a light emitting period of the pixel PXL.

In some embodiments, end portions (for example, P-type end portions) of the light emitting elements LD forming each light source unit LSU may be connected to the pixel circuit PXC through an electrode (for example, the first pixel electrode ETL1 of each pixel PXL) of the light source unit LSU, and may be connected to the first power source VDD through the pixel circuit PXC and the first power line PL1. For example, another end portions (for example, N-type end portions) of the light emitting elements LD may be commonly connected to the second power source VSS through another electrode (for example, the second electrode ETL2 of each pixel PXL) of the light source unit LSU and the second power wire PL2.

The light emitting elements LD may emit light of a luminance corresponding to a driving current supplied through the corresponding pixel circuit PXC. For example, during each frame period, the pixel circuit PXC may supply a driving current corresponding to a grayscale value to be displayed in the corresponding frame to the light source unit LSU. The driving current supplied to the light source unit LSU may be divided to flow in the light emitting elements LD that are connected in a forward-bias direction. Therefore, in case that each light emitting element LD emits light of a luminance corresponding to the current flowing therein, the light source unit LSU may emit light having a luminance corresponding to the driving current.

In an embodiment, the light source unit LSU may further include at least one ineffective light source in addition to the light emitting elements LD forming each effective light source. For example, at least one reverse-biased light emitting element LDrv may be further connected between the first and second electrodes ETL1 and ETL2.

Each reverse-biased light emitting element may be connected in parallel between the first and second electrodes ETL1 and ETL2 together with the light emitting elements LD forming the effective light sources, but may be connected between the first and second electrodes ETL1 and ETL2 in the opposite direction with respect to the light emitting elements LD. For example, an N-type end portion of the reverse-biased light emitting element LDrv may be connected to the first power source VDD via the first electrode ETL1 and pixel circuit PXC, and a P-type end portion of the reverse-biased light emitting element LDrv may be connected to the second power source VSS via the second electrode ETL2. The reverse-biased light emitting element LDrv may maintain a deactivated state although a driving voltage (for example, driving voltage of forward-bias direction) is applied between the first and second electrodes ETL1 and ETL2. Thus, the reverse-biased light emitting element LDrv may maintain a substantially non-light emitting state.

In some embodiments, at least one pixel PXL may further include at least one ineffective light source that is not fully connected between the first and second electrodes ETL1 and ETL2. For example, at least one pixel PXL may further include at least one ineffective light emitting element that is positioned within the light source unit LSU, and of which respective end portions are not connected to the first and second electrodes ETL1 and ETL2.

The pixel circuit PXC may be connected between the first power source VDD and the first electrode ETL1. The pixel circuit PXC may be connected to a scan line Si and a data line Dj of the pixel PXL. In case that the pixel PXL is disposed in an i-th horizontal line (or row) (where i is a natural number) and a j-th vertical line (or column) (where j is a natural number) of the display area DA, the pixel circuit PXC of the pixel PXL may be connected to an i-th scan line Si and a j-th data line Dj of the display area DA.

In some embodiments, the pixel circuit PXC may include transistors and at least one capacitor. For example, the pixel circuit PXC may include a first transistor T1, a second transistor T2, and a storage capacitor Cst.

The first transistor T1 may be connected between the first power source VDD and the light source unit LSU. For example, a first electrode (for example, a source electrode) of the first transistor T1 may be connected to the first power source VDD, and a second electrode (for example, a drain electrode) of the first transistor T1 may be connected to the first electrode ETL1. For example, a gate electrode of the first transistor T1 may be connected to a first node N1. The first transistor T1 may control a driving current supplied to the light source unit LSU in response to a voltage of the first node N1. For example, the first transistor T1 may be a driving transistor that controls a driving current of the pixel PXL.

The second transistor T2 may be connected between the data line Dj and the first node N1. For example, a first electrode (for example, a source electrode) of the second transistor T2 may be connected to the data line Dj, and a second electrode (for example, a drain electrode) of the second transistor T2 may be connected to the first node N1. For example, a gate electrode of the second transistor T2 may be connected to the scan line Si. In case that a scan signal SSi of a gate-on voltage (for example, a low level voltage) is supplied from the scan line Si, the second transistor T2 may be turned on to electrically connect the data line Dj and the first node N1.

During each frame period, a data signal DSj of the corresponding frame may be supplied to the data line Dj, and the data signal DSj may be transmitted to the first node N1 through the turned-on transistor T2 during a period in which the scan signal SSi of the gate-on voltage is supplied. For example, the second transistor T2 may be a switching transistor for transmitting each data signal DSj to the inside of the pixel PXL.

An electrode of the storage capacitor Cst may be connected to the first power source VDD, and another electrode thereof may be connected to the first node N1. The storage capacitor Cst may be charged with a voltage the corresponding to the data signal DSj supplied to the first node N1 during each frame period.

FIG. 6 illustrates the transistors included in the pixel circuit PXC, for example, the first and second transistors T1 and T2 as P-type transistors, but embodiments are not limited thereto. For example, at least one of the first and second transistors T1 and T2 may be changed or modified as an N-type transistor.

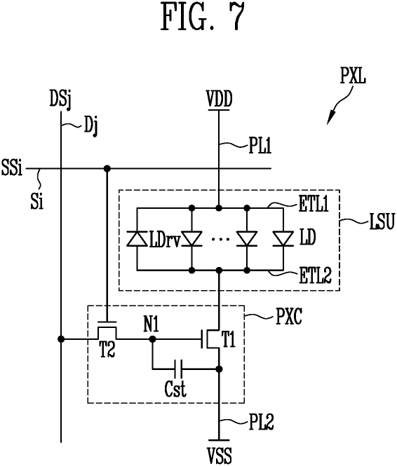

For example, as shown in FIG. 7, each of the first and second transistors T1 and T2 may be an N-type transistor. For example, a gate-on voltage of the scan signal SSi for writing the data signal DSj supplied to the data line Dj for each frame period to the pixel PXL may be a high level voltage (referred to as a “gate-high voltage”). A voltage of the data signal DSj for turning on the first transistor T1 may be a voltage of a level opposite to that in the embodiment of FIG. 6. In the embodiment of FIG. 6, the data signal DSj of a lower voltage may be supplied as a grayscale value to be displayed increases. In the embodiment of FIG. 7, the data signal of a higher voltage DSj may be supplied as a grayscale value to be expressed increases. In another example, the first and second transistors T1 and T2 may be transistors of different conductive types. For example, one of the first and second transistors T1 and T2 may be a P-type transistor, and the other thereof may be an N-type transistor.

In an embodiment, interconnection positions of the pixel circuit PXC and the light source unit LSU may be changed or modified. For example, as shown in FIG. 7, in case that both the first and second transistors T1 and T2 included in the pixel circuit PXC are N-type transistors, the pixel circuit PXC may be connected between the light source unit LSU and the second power source VSS, the storage capacitor Cst may be connected between the first node N1 and the second power source VSS. However, embodiments are not limited thereto. In another example, in case that the pixel circuit PXC is formed as N-type transistors, the pixel circuit PXC may be connected between the first power source VDD and the light source unit LSU, and/or the storage capacitor Cst may be connected between the first power source VDD and the first node N1.

The configuration and operation of the pixel PXL shown in FIG. 7 are substantially similar to those of the pixel PXL of FIG. 7, except that connection positions of some circuit elements and voltage levels of control signals (for example, the scan signal SSi and the data signal DSj) are changed in case that the type of the first and second transistors T1 and T2 is changed. Therefore, a detailed description of the pixel PXL of FIG. 7 will be omitted for descriptive convenience.

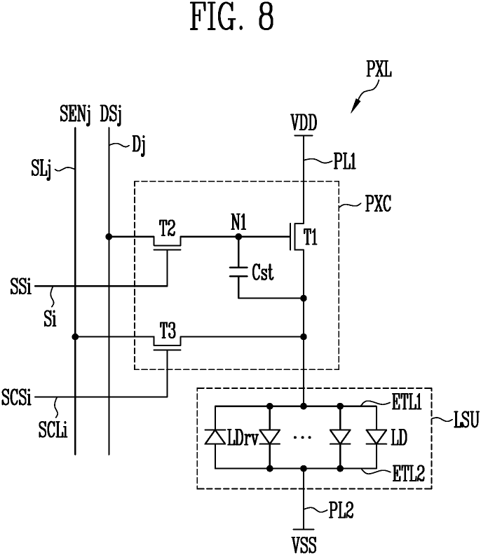

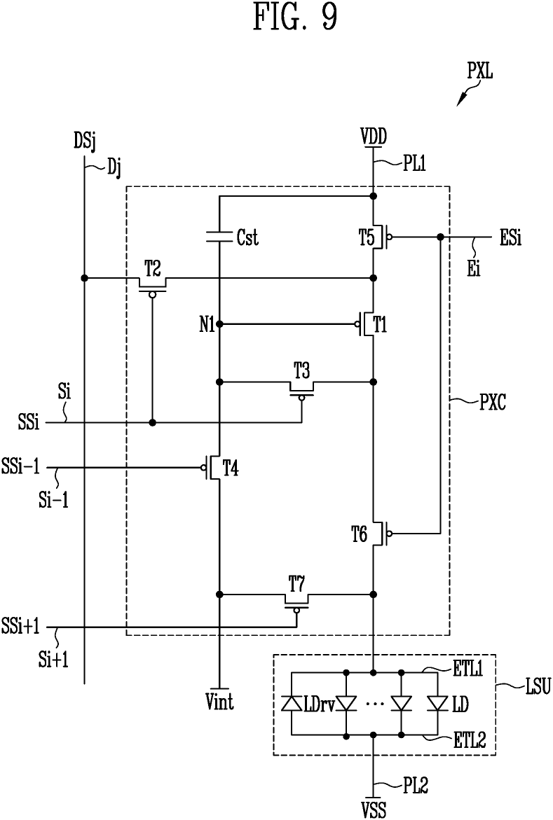

For example, the structure of the pixel circuit PXC is not limited to the embodiments illustrated in FIG. 6 and FIG. 7. For example, the pixel circuit PXC may be formed as the embodiment illustrated in FIG. 8 or FIG. 9. For example, the pixel circuit PXC may be formed as a pixel circuit having various structures and/or driving methods.

Referring to FIG. 8, the pixel circuit PXC may be further connected to a sensing control line SCLi and a sensing line SLj. For example, the pixel circuit PXC of the pixel PXL at an i-th horizontal line and a j-th vertical line of the display area DA may be connected to an i-th sensing control line SCLi and a j-th sensing line SLj of the display area DA. The pixel circuit PXC may further include a third transistor T3. In another example, the sensing line SLj may be omitted, and the characteristics of the pixel PXL may be detected by detecting a sensing signal SENj through the data line Dj of the corresponding pixel PXL (or adjacent pixel),

The third transistor T3 may be connected between the first transistor T1 and the sensing line SLj. For example, an electrode of the third transistor T3 may be connected to an electrode (for example, a source electrode) of the first transistor T1 connected to the first electrode ETL1, and another electrode of the third transistor T3 may be connected to the sensing line SLj. In case that the sensing line SLj is omitted, another electrode of the third transistor T3 may be connected to the data line Dj.

A gate electrode of the third transistor T3 may be connected to the sensing control line SCLi. In case that the sensing control line SCLi is omitted, the gate electrode of the third transistor T3 may be connected to the scan line Si. The third transistor T3 may be turned on by a sensing control signal SCSi of a gate-on voltage (for example, a high level voltage) supplied to the sensing control line SCLi during a sensing period to electrically connect the sensing line SLj and the first transistor T1.

In some embodiments, the sensing period may be a period for extracting (or sensing) characteristics (for example, a threshold voltage of the first transistor T1) of each of the pixels PXL disposed in the display area DA. During the sensing period, the first transistor T1 may be turned on by supplying a reference voltage at which the first transistor T1 may be turned on to the first node N1 through the data line Dj and the second transistor T2 and by connecting each pixel PXL to a current source or the like. For example, by supplying the sensing control signal SCSi of a gate-on voltage to the third transistor T3 to turn on the third transistor T3, the first transistor T1 may be connected to the sensing line SLj. Thereafter, the sensing signal SENj may be obtained through the sensing line SLj, and the characteristics of each pixel PXL in addition to the threshold voltage of the first transistor T1 may be detected by using the sensing signal SENj. Information of the characteristics of each pixel PXL may be used to convert image data so that a characteristic difference between the pixels PXL disposed in the display area DA may be compensated.

FIG. 8 illustrates an embodiment in which the first, second, and third transistors T1, T2, and T3 are all N-type transistors, but embodiments are not limited thereto. For example, at least one of the first, second, and third transistors T1, T2, and T3 may be changed or modified to a P-type transistor. FIG. 8 illustrates an embodiment in which the light source unit LSU is connected between the pixel circuit PXC and the second power source VSS, but embodiments are not limited thereto. In another example, the light source unit LSU may be connected between the first power source VDD and the pixel circuit PXC.

Referring to FIG. 9, the pixel circuit PXC may be further connected to at least one other scan line or control line in addition to the scan line Si of the corresponding horizontal line. For example, the pixel circuit PXC of the pixel PXL disposed in the i-th horizontal line of the display area DA may be further connected to an (i-1)-th scan line Si-1 and/or an (i+1)-th scan line Si+1. For example, the pixel circuit PXC may be further connected to another power source in addition to the first and second power sources VDD and VSS. For example, the pixel circuit PXC may be connected to an initialization power source Vint. In an embodiment, the pixel circuit PXC may include first to seventh transistors T1 to T7 and a storage capacitor Cst.

The first transistor T1 may be connected between the first power source VDD and the light source unit LSU. For example, an electrode (for example, a source electrode) of the first transistor T1 may be connected to the first power source VDD through the fifth transistor T5 and the first power line PL1, and another electrode (for example, a drain electrode) of the first transistor T1 may be connected to an electrode (for example, the first electrode ETL1) of the light source unit LSU via the sixth transistor T6. For example, a gate electrode of the first transistor T1 may be connected to a first node N1. The first transistor T1 may control a driving current supplied to the light source unit LSU in response to a voltage of the first node N1.

The second transistor T2 may be connected between the data line Dj and an electrode (for example, the source electrode) of the first transistor T1. For example, a gate electrode of the second transistor T2 may be connected to the corresponding scan line Si. In case that a scan signal SSi of a gate-on voltage is supplied from the scan line Si, the second transistor T2 may be turned on to electrically connect the data line Dj to an electrode of the first transistor T1. Therefore, in case that the second transistor T2 is turned on, the data signal DSj supplied from the data line Dj may be transmitted to the first transistor T1.

The third transistor T3 may be connected between other electrode (for example, the drain electrode) of the first transistor T1 and the first node N1. For example, a gate electrode of the third transistor T3 may be connected to the corresponding scan line Si. In case that the scan signal SSi of the gate-on voltage is supplied from the scan line Si, the third transistor T3 may be turned on to connect the first transistor T1 in a form of a diode. Accordingly, during the period in which the scan signal SSi of the gate-on voltage is supplied, the first transistor T1 may be turned on in a diode-connected form. Accordingly, the data signal DSj from the data line Dj may sequentially pass through the second transistor T2, the first transistor T1, and the third transistor T3 to be supplied to the first node N1. Accordingly, the storage capacitor Cst may be charged with a voltage corresponding to the data signal DSj and the threshold voltage of the first transistor T1.

The fourth transistor T4 may be connected between the first node N1 and the initialization power source Vint. A gate electrode of the fourth transistor T4 may be connected to a previous scan line, for example, an (i-1)-th scan line Si-1. In case that the scan signal SSi-1 of the gate-on voltage is supplied to the (i-1)-th scan line Si-1, the fourth transistor T4 may be turned on to transmit a voltage of the initialization power source Vint to the first node N1.

In some embodiments, the voltage of the initialization power source Vint may be equal to or less than the lowest voltage of the data signal DSj. Before the data signal DSj of the corresponding frame is supplied to each pixel PXL, the first node N1 may be initialized to the voltage of the initialization power supply Vint by the first scan signal SSi-1 of the gate-on voltage supplied to the (i-1)-th scan line Si-1. Accordingly, regardless of the voltage of the data signal DSj of the previous frame, the first transistor T1 may be diode-connected in the forward-bias direction in case that the scan signal SSi of the gate-on voltage is supplied to the i-th scan line Si. Accordingly, the data signal DSj of the corresponding frame may be transmitted to the first node N1.

The fifth transistor T5 may be connected between the first power source VDD and the first transistor T1. For example, a gate electrode of the fifth transistor T5 may be connected to the corresponding light emitting control line, for example, an i-th light emitting control line Ei. In case that a light emitting control signal ESi of a gate-off voltage (for example, a high level voltage) is supplied to the light emitting control line Ei, the fifth transistor T5 may be turned off, and may be turned on in other cases.

The sixth transistor T6 may be connected between the first transistor T1 and the light source unit LSU. For example, a gate electrode of the sixth transistor T6 may be connected to the corresponding light emitting control line, for example, the i-th light emitting control line Ei. In case that a light emitting control signal ESi having the gate-off voltage is supplied to the light emitting control line Ei, the sixth transistor T6 may be turned off, and may be turned on in other cases.

The fifth and sixth transistors T5 and T6 may control a light emitting period of the pixel PXL. In case that the fifth and sixth transistors T5 and T6 are turned on, a current path in which a driving current flows from the first power source VDD to the second power source VSS through the fifth transistor T5, the first transistor T1, the sixth transistor T6, and the light source unit LSU in sequence, may be formed. In case that the fifth and/or sixth transistors T5 and T6 are turned off, the current path may be blocked, and light emitting of the pixel PXL may be prevented.

The seventh transistor T7 may be connected between an electrode of the light source unit LSU (for example, the first electrode ETL1) and the initialization power source Vint. A gate electrode of the seventh transistor T7 may be connected to a scan line for selecting the pixels PXL of a next horizontal line, for example, to an (i+1)-th scan line Si+1. In case that a scan signal SSi+1 of the gate-on voltage is supplied to the (i+1)-th scan line Si+1, the seventh transistor T7 may be turned on to supply the voltage of the initialization power source Vint to an electrode of the light source unit LSU (for example, the first pixel electrode ETL1). Accordingly, during each initialization period in which the voltage of the initialization power source Vint is transmitted to the light source unit LSU, the voltage of an electrode of the light source unit LSU may be initialized.

For example, the control signal and/or the initialization power source Vint for controlling the operation of the seventh transistor T7 may be variously changed. In another example, the gate electrode of the seventh transistor T7 may be connected the scan line of the corresponding horizontal line, e.g., the i-th scan line Si or the scan line of the previous horizontal line, for example, the (i-1)-th scan line Si-1. In case that the scan signal SSi or SSi-1 of the gate-on voltage is supplied to the i-th scan line Si or the (i-1)-th scan line Si-1, the seventh transistor T7 may be turned on to supply the voltage of the initialization power source Vint to an electrode of the light source unit LSU. Accordingly, during each frame period, the pixel PXL may emit light with a more uniform luminance in response to the data signal DSj. In some embodiments, the fourth transistor T4 and the seventh transistor T7 may be connected to respective initialization power sources having different potentials. In some embodiments, initialization power sources may be supplied to the pixel, and the first node N1 and the first electrode ETL1 may be initialized by initialization power sources having different potentials.

The storage capacitor Cst may be connected between the first power source VDD and the first node N1. The storage capacitor Cst may store the data signal DSj supplied to the first node N1 in each frame period and a voltage corresponding to the threshold voltage of the first transistor T1.

FIG. 9 illustrates the transistors included in the pixel circuit PXC, for example, the first to seventh transistors T1 to T7 as P-type transistors, but embodiments are not limited thereto. For example, at least one of the first to seventh transistors T1 and T7 may be formed as an N-type transistor.

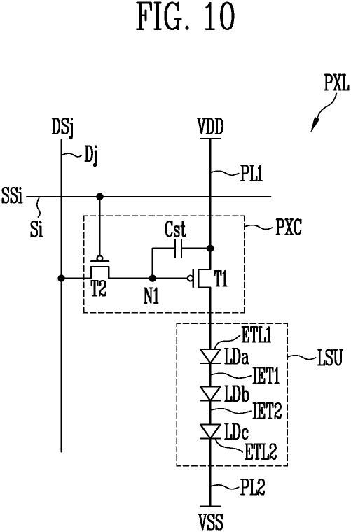

FIG. 6 to FIG. 9 illustrate the embodiments in which effective light sources forming each light source unit LSU, e.g., the light emitting elements LD are all connected in parallel, but embodiments are not limited thereto. In another example, as shown in FIG. 10, the light source unit LSU of each pixel PXL may include at least two stages in series. In describing embodiments of FIG. 10, a detailed description of the configuration (for example, the pixel circuit PXC) that is similar to or the same as the embodiments of FIG. 6 to FIG. 9 will be omitted for descriptive convenience.

Referring to FIG. 10, the light source unit LSU may include at least two light emitting elements connected in series to each other. For example, the light source unit LSU may include first to third light emitting elements LDa, LDb, and LDc connected in series in a forward-bias direction between the first power source VDD and the second power source VSS. Each of the first, second, and third light emitting elements LDa, LDb, and LDc may form an effective light source.

A first end portion (for example, P-type end portion) of the first light emitting element LDa may be connected to the first power source VDD via the first electrode ETL1 (e.g., first pixel electrode) of the light source unit LSU. For example, a second end portion (for example, N-type end portion) of the first light emitting element LDa may be connected to a first end portion (for example, P-type end portion) of the second light emitting element LDb through a first middle electrode IET1.

The first end portion (for example, P-type end portion) of the second light emitting element LDb may be connected to a second end portion of the first light emitting element LDa. For example, the second end portion (for example, N-type end) of the second light emitting element LDb may be connected to a first end portion (for example, P-type end portion) of the third light emitting element LDc through a second middle electrode IET2.

The first end portion of the third light emitting element LDc (for example, P-type end portion) may be connected to the second end portion of the second light emitting element LDb. For example, a second end portion of the third light emitting element LDc (for example, N-type end portion) may be connected to the second power supply VSS via the second electrode (e.g., second pixel electrode ETL2) of the light source unit LSU. In the above-described manner, the first, second, and third light emitting elements LDa, LDb, and LDc may be sequentially connected in series between the first and second electrodes ETL1 and ETL2 of the light source unit LSU.

FIG. 10 illustrates the embodiment in which light emitting elements LD are connected in a three-stage series structure, but embodiments are not limited thereto. In another example, two light emitting elements LD may be connected in a two-stage series structure, or four or more light emitting elements LD may be connected in a four-stage or more series structure.

Assuming that the same luminance is displayed using the light-emitting elements LD of the same condition (for example, the same size and/or number), in the light source unit LSU having a structure in which the light emitting elements LD are connected in series compared to the light source unit LSU having a structure in which the light emitting elements LD are connected in parallel, a voltage applied between the first and second electrodes ETL1 and ETL2 may increase, a driving current flowing through the light source unit LSU may decrease. Therefore, in case that the light source unit LSU of each pixel PXL is formed by applying the serial structure, a panel current flowing through the display panel PNL may be reduced.

In some embodiments, at least one serial stage may include light emitting elements LD connected in parallel to each other. For example, the light source unit LSU may be formed in a series/parallel mixed structure.

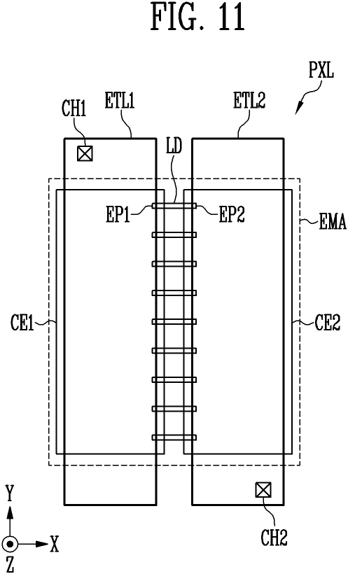

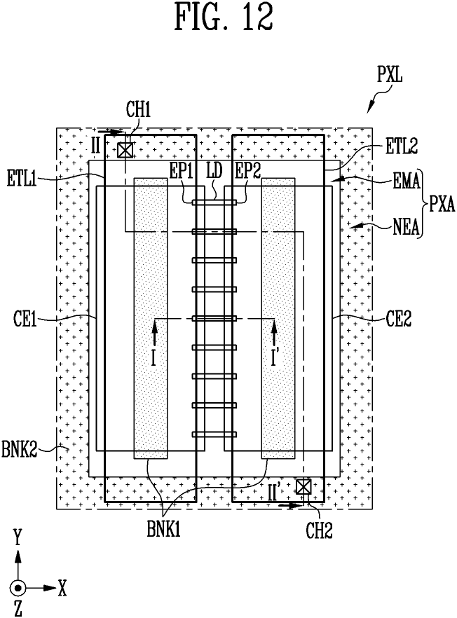

FIG. 11 and FIG. 12 illustrate schematic top plan views of a pixel according to an embodiment.

In FIG. 11 and FIG. 12, a structure of the pixel PXL is illustrated based on the light source unit LSU of each pixel PXL. However, in some embodiments, each pixel PXL may selectively further include circuit elements (for example, circuit elements forming each pixel circuit PXC) connected to the light source unit LSU.

FIG. 11 and FIG. 12 illustrate an embodiment in which each light source unit LSU is connected to a power line (for example, the first and/or second power lines PL1 and PL2), a circuit element (for example, at least one circuit element forming the pixel circuit PXC), and/or a signal line (for example, the scan line Si and/or the data line Dj), through first and second contact holes CH1 and CH2. However, embodiments are not limited thereto. In another example, at least one of the first and second electrodes ETL1 and ETL2 of each pixel PXL may be connected (e.g., directly connected) to a power line and/or signal line without passing through a contact hole and/or a middle line.

Referring to FIG. 11, the pixel PXL may include the first electrode ETL1 and the second electrode ETL2 disposed in each light emitting area EMA, and at least one light-emitting element LD (for example, the light emitting elements LD connected between the first and second electrodes ETL1 and ETL2) disposed between the first and second electrodes ETL1 and ETL2. For example, the pixel PXL may further include a first contact electrode CE1 and a second contact electrode CE2 for electrically connecting the light emitting element LD between the first and second electrodes ETL1 and ETL2.

The first electrode ETL1 and the second electrode ETL2 may be disposed in the light emitting area EMA of each pixel PXL. The light-emitting area EMA may be an area in which the light-emitting elements LD (e.g., effective light sources connected between the first and second electrodes ETL1 and ETL2) forming the light source unit LSU of each pixel PXL are disposed. For example, an area of electrodes connected to the light emitting elements LD (for example, the first and second electrodes ETL1 and ETL2 and/or the first and second contact electrodes CE1 and CE2) or of the above-mentioned electrodes may be disposed in the light emitting area EMA.

The first and second electrodes ETL1, and ETL2 may be disposed apart from each other. For example, the first and second electrodes ETL1 and ETL2 may be spaced apart side by side by an interval in a first direction (e.g., X-axis direction) in each light emitting area EMA.

For example, before the process of forming the pixel PXL, before the alignment of the light emitting elements LD is completed, the first electrodes ETL1 of the pixels PXL disposed in the display area DA may be connected (e.g., electrically connected) to each other, and the second electrodes ETL2 of the pixels PXL may be connected (e.g., electrically connected) to each other. The first and second electrodes ETL1 and ETL2 may receive a first alignment signal (or first alignment voltage) and a second alignment signal (or second alignment voltage), respectively, in an alignment step of the light emitting elements LD. For example, one of the first and second electrodes ETL1 and ETL2 may be supplied with an AC-type alignment signal, and the other of the first and second electrodes ETL1 and ETL2 may be supplied with an alignment voltage (for example, a ground voltage) having a constant voltage level. For example, an alignment signal may be applied to the first and second electrodes ETL1 and ETL2 in the alignment step of the light emitting elements LD. Accordingly, an electric field may be formed between the first and second electrodes ETL1 and ETL2. The light emitting elements LD provided in the light emitting area EMA of the pixel PXL may be self-aligned between the first and second electrodes ETL1 and ETL2 by the electric field. After the alignment of the light emitting elements LD is completed, by disconnecting the at least first electrodes ETL1 between the pixels PXL, the pixels PXL may be formed in a form capable of being individually driven.

The first and second electrodes ETL1 and ETL2 may have various shapes. For example, as shown in FIG. 11 and FIG. 12, each of the first and second electrodes ETL1 and ETL2 may have a bar-like shape extending in a direction. For example, each of the first and second electrodes ETL1 and ETL2 may have a bar shape extending in a second direction (e.g., Y-axis direction) intersecting (for example, orthogonal to) the first direction (e.g., X-axis direction).

Although FIG. 11 and FIG. 12 illustrate the case in which a first electrode ETL1 and a second electrode ETL2 are disposed in each light emitting area EMA, the number and the disposition of the first and second electrodes ETL1 and ETL2 disposed in the light emitting area EMA of the pixel PXL may be variously changed. In another example, first electrodes ETL1 and/or second electrodes ETL2 may be disposed in the light emitting area EMA of each pixel PXL.

In case that the first electrodes ETL1 are disposed in a pixel PXL, the first electrodes ETL1 may be integrally or non-integrally connected to each other. For example, the first electrodes ETL1 may be integrally connected, or may be connected to each other by a bridge pattern positioned on a different layer (for example, a circuit layer in which the pixel circuit PXC is disposed) from the first electrodes. In case that the second electrodes ETL2 are disposed in a pixel PXL, the second electrodes ETL2 may be integrally or non-integrally connected to each other. For example, the second electrodes ETL2 may be integrally connected to each other, or may be connected to each other by a bridge pattern positioned on a different layer from the second electrodes. For example, the shape, number, arrangement direction, and/or mutual disposed relationship of the first and second electrodes ETL1 and ETL2 disposed in each pixel PXL may be variously changed.

The first electrode ETL1 may be electrically connected to a circuit element (for example, at least one transistor forming the pixel circuit PXC), a power line (for example, the first power line PL1), and/or a signal line (for example, the scan line Si, the data line Dj, or a control line), through the first contact hole CH1. However, embodiments are not limited thereto. In another example, the first electrode ETL1 may be connected (e.g., directly connected) to a power wire or signal wire.

In an embodiment, the first electrode ETL1 may be electrically connected to a circuit element disposed thereunder through the first contact hole CH1, and to a first wire through the circuit element. The first wire may be the first power wire PL1 for supplying the first power source VDD, but embodiments are not limited thereto. For example, the first wire may be a signal wire to which a first driving signal (for example, a scan signal, a data signal, or a control signal) is supplied.

The second electrode ETL2 may be electrically connected to a circuit element (for example, at least one transistor forming the pixel circuit PXC), a power line (or wire) (for example, the second power line (or wire) PL2), and/or a signal line (for example, the scan line Si, the data line Dj, or a control line), through the second contact hole CH2. However, embodiments are not limited thereto. In another example, the second electrode ETL2 may be connected (e.g., directly connected) to a power wire or signal wire.

In an embodiment, the second electrode ETL2 may be connected (e.g., electrically connected) to the second wire disposed thereunder through the second contact hole CH2. The second wire may be a second power wire PL2 for supplying the second power source VSS, but embodiments are not limited thereto. For example, the second wire may be a signal wire to which a second driving signal (for example, a scan signal, a data signal, or a control signal) is supplied.

The light emitting elements LD may be disposed between the first electrode ETL1 and the second electrode ETL2. For example, each light emitting element LD may be disposed between the first electrode ETL1 and the second electrode ETL2 in the first direction (e.g., X-axis direction), and thus may be connected (e.g., electrically connected) between the first and second electrodes ETL1 and ETL2.

FIG. 11 and FIG. 12 illustrate that all of the light emitting elements LD are uniformly aligned in the first direction (e.g., X-axis direction), but embodiments are not limited thereto. For example, at least one of the light emitting elements LD may be arranged in an oblique direction (or diagonal direction) between the first and second electrodes ETL1 and ETL2.

In some embodiments, each light emitting element LD may be an ultra-small light emitting element using a material having an inorganic crystal structure, for example, having a size as small as nano-scale or micro-scale. For example, each light emitting element LD may be an ultra-small light emitting element having a size of a range of a nano scale to a micro scale, as shown in FIG. 1 to FIG. 4. However, the type and/or size of the light emitting element LD may be variously changed according to each light emitting device using the light emitting element LD as a light source, for example, according to a design condition of the pixel PXL.

Each light emitting element LD may include the first end portion EP1 disposed toward the first electrode ETL1 and the second end EP2 disposed toward the second electrode ETL2. The first end portion EP1 of each of the light emitting elements LD may be electrically connected to the first electrode ETL1, and the second end portion EP2 of each of the light emitting elements LD may be electrically connected to the second electrode ETL2. For example, the first end portion EP1 of each of the light emitting elements LD may be electrically connected to the first electrode ETL1 through the first contact electrode CE1, and the second end portion EP2 of each of the light emitting elements LD may be electrically connected to the second electrode ETL2 through the second contact electrode CE2. In another example, the first end portion EP1 of each of the light emitting elements LD may directly contact the first electrode ETL1, and thus, may be connected to the first electrode ETL1. For example, the second end portion EP2 of each of the light emitting elements LD may directly contact the second electrode ETL2, and thus, may be connected to the second electrode ETL2. For example, the first contact electrode CE1 and/or the second contact electrode CE2 may be selectively formed.

In some embodiments, the light emitting elements LD may be prepared in a form dispersed in a solution to be supplied to the light emitting area EMA of the pixel PXL through various methods including an inkjet method or a slit coating method. For example, the light emitting elements LD may be mixed with a volatile solvent, and then may be supplied to the light emitting area EMA of each pixel PXL. For example, in case that an alignment voltage (or alignment signal) is applied to the first and second electrodes ETL1 and ETL2 of the pixels PXL, an electric field is formed between the first and second electrodes ETL1 and ETL2, and thus, the light emitting elements LD are aligned between the first and second electrodes ETL1 and ETL2. After the light emitting elements LD are aligned, the light emitting elements LD may be stably arranged between the first and second electrodes ETL1 and ETL2 by volatilizing the solvent or eliminating it in other ways.

In some embodiments, the first contact electrode CE1 and second contact electrode CE2 may be formed on end portions (e.g., opposite end portions) of the light emitting elements LD, for example, the first and second end portions EP1 and EP2 thereof, respectively. Accordingly, the light emitting elements LD may be more stably connected between the first and second electrodes ETL1 and ETL2.

The first contact electrode CE1 may be disposed on the first electrode ETL1 and the first end portion EP1 of the light emitting element LD so as to overlap the first electrode ETL1 and the first end portion EP1 of the at least one light emitting element LD adjacent to the first electrode ETL1. The first contact electrode CE1 may connect (e.g., electrically connect) the first electrode ETL1 and the first end portions EP1 of the light emitting elements LD. For example, the first contact electrode CE1 may stably fix the first end portions EP1 of the light emitting elements LD. In another example, in case that the first contact electrode CE1 is not formed, the first end portions EP1 of the light emitting elements LD may overlap the first electrode ETL1 adjacent thereto to be connected (e.g., directly connected) to the first electrode ETL1.

The second contact electrode CE2 may be disposed on the second electrode ETL2 and the second end portion EP2 of the light emitting element LD so as to overlap the second electrode ETL2 and the second end portion EP2 of the at least one light emitting element LD adjacent to the second electrode ETL2. The second contact electrode CE2 may connect (e.g., electrically connect) the second electrode ETL2 and the second end portions EP2 of the light emitting elements LD. For example, the second contact electrode CE2 may stably fix the second end portions EP2 of the light emitting elements LD. In another example, in case that the second contact electrode CE2 is not formed, the second end portions EP2 of the light emitting elements LD may overlap the second electrode ETL2 adjacent thereto to be connected (e.g., directly connected) to the second electrode ETL2.

In the above-described embodiment, each light emitting element LD connected in a forward-bias direction between the first and second electrodes ETL1 and ETL2 may form an effective light source of the corresponding pixel PXL. For example, the effective light sources may be gathered to form the light source unit LSU of the corresponding pixel PXL.

In case that the first power source VDD (or a first control signal in addition to a scan signal or a data signal) is applied to the first end portions EP1 of the light emitting elements LD via the first power line PL1, the first electrode ETL1, and/or the first contact electrode CE1 and in case that the second power source VSS (or a second control signal in addition to a scanning signal or a data signal) is applied to the second end portions EP2 of the light emitting elements LD via the second power line PL2, the second electrode ETL2, and/or the second contact electrode CE2, the light emitting elements LD connected in a forward-bias direction between the first and second electrodes ETL1 and ETL2 may emit light. Accordingly, light is emitted from the pixel PXL.

Referring to FIG. 12, the pixel PXL may further include the first bank BNK1 overlapping the first and second electrodes ETL1 and ETL2, and the second bank BNK2 surrounding each light emitting area EMA.

The first bank BNK1 (referred to as a “definition wall”) may be disposed under the first and second electrodes ETL1 and ETL2. For example, the first bank BNK1 may be disposed under the first and second electrodes ETL1 and ETL2 so as to respectively overlap areas of the first and second electrodes ETL1 and ETL2.

As the first bank BNK1 is disposed under an area of each of the first and second electrodes ETL1 and ETL2, the first and second electrodes ETL1, and ETL2 may be protrude in an upper direction (a third direction (e.g., Z-axis direction)) in an area in which the first bank BNK1 is formed. This first bank BNK1 may form a reflective bank (referred to as a “reflective definition wall”) together with the first and second electrodes ETL1 and ETL2. For example, the first and second electrodes ETL1 and ETL2 and/or the first bank BNK1 may be formed of a reflective material, or at least one material layer having a reflective characteristic may be formed on the protruding sidewalls of the first and second electrodes ETL1 and ETL2 and/or the first bank BNK1. Accordingly, the light emitted from the first and second end portions EP1 and EP2 of the light emitting elements LD facing the first and second electrodes ETL1 and ETL2 may be induced to be more directed toward a front direction of the display panel PNL. In case that an area of each of the first and second electrodes ETL1 and ETL2 is protruded in the upper direction by the first bank BNK1, a ratio of the light directed to the front direction (the third direction (e.g., Z-axis direction)) of the display panel PNL with respect to the light generated from the pixel PXL may be increased, and thus, it is possible to improve an optical efficiency (or light output efficiency) of the pixel PXL.

In some embodiments, the first bank BNK1 may be omitted. For example, the first and second electrodes ETL1 and ETL2 may be substantially flat, or may have a protrusion and depression surface. For example, by forming each of the first and second electrodes ETL1 and ETL2 to have a different thickness for each area to form a protrusion and depression surface, an area of the first and second electrodes ETL1 and ETL2 may be protruded in the upper direction. Accordingly, the light emitted from the light emitting elements LD may be induced to be directed toward the front direction (e.g., the third direction or Z-axis direction) of the display panel PNL.

The second bank BNK2 may be a structure defining the light emitting area EMA of each pixel PXL, and may be, for example, a pixel defining layer. For example, the second bank BNK2 may be disposed in a boundary area of each pixel area PXA in which the pixel PXL is provided and/or in an area between the pixels PXL adjacent thereto so as to surround the light emitting area EMA of each pixel PXL.

The second bank BNK2 may overlap an area (for example, end portions) of the first and second electrodes ETL1 and ETL2 as shown in FIG. 12. For example, the first and second contact holes CH1 and CH2 may be formed in the non-light emitting area NEA so as to overlap the second bank BNK2, or may be formed inside of the light emitting area EMA so as to not overlap the second bank BNK2.

The second bank BNK2 may include at least one light-blocking and/or reflective material to prevent light leakage between adjacent pixels PXL. For example, the second bank BNK2 may include various types of black matrix materials (for example, at least one light blocking material currently known), and/or a color filter material of a specific color. For example, the second bank BNK2 may be formed in a black opaque pattern to block light transmission. In an embodiment, a reflective layer may be formed on a surface (for example, a side surface) of the second bank BNK2 to further increase a light output efficiency of the pixel PXL.

For example, the second bank BNK2 may function as a dam structure that defines each light emitting area EMA in which the light emitting elements LD are supplied at the step of supplying the light emitting elements LD to each pixel PXL. For example, each light emitting area EMA is defined by the second bank BNK2, so that a desired type and/or amount of light emitting element ink may be supplied into the light emitting area EMA.

In an embodiment, the first banks BNK1 and the second bank BNK2 may be simultaneously formed in the same layer and by the same process. In another example, the first banks BNK1 and the second bank BNK2 may be formed in the same or different layer and by a separate process.

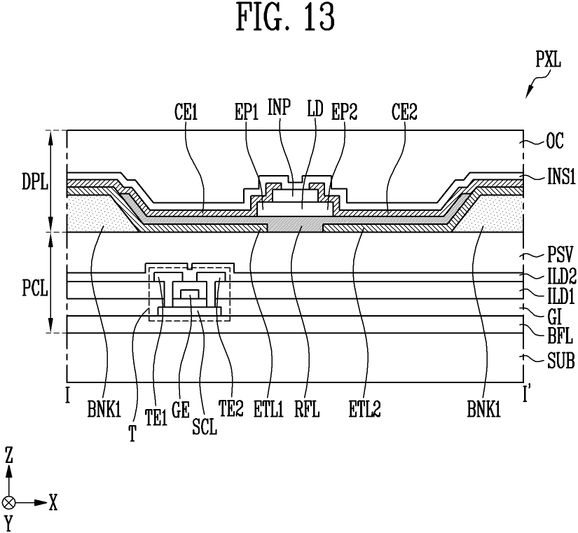

FIG. 13 to FIG. 15 illustrate schematic cross-sectional views of a pixel according to an embodiment.

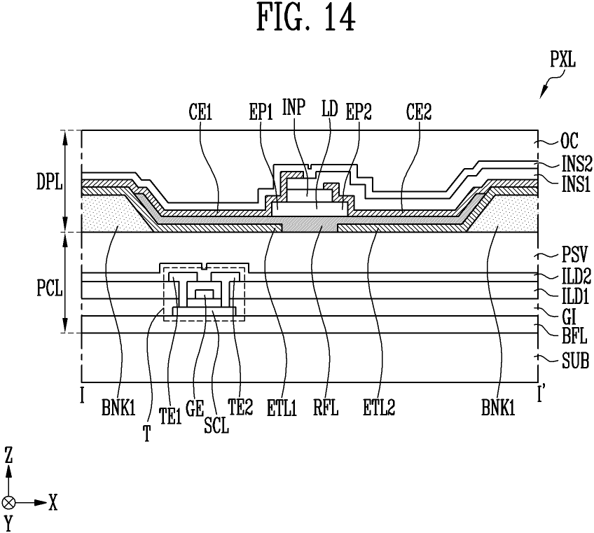

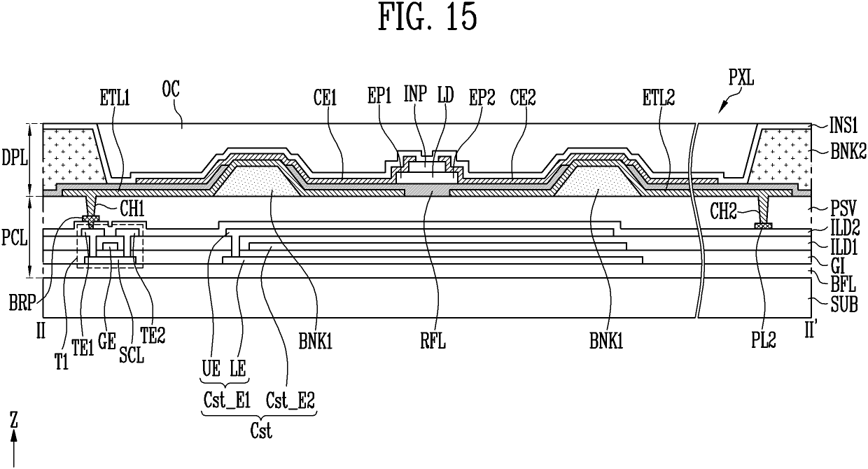

For example, FIG. 13 and FIG. 14 illustrate schematic cross-sectional views taken along line I-I′ of FIG. 12, and FIG. 15 illustrates a schematic cross-sectional view taken along line II-II′ of FIG. 12.

In order to show various circuit elements forming the pixel circuit PXC, FIG. 13 and FIG. 14 illustrate an arbitrary transistor T among the circuit elements, and FIG. 15 illustrates the transistor (for example, the first transistor T1 of FIG. 6) and the storage capacitor Cst connected to the first electrode ETL1 among the circuit elements, but each pixel PXL may include transistors. Hereinafter, in case that it is not necessary to separately specify the first transistor T1, the first transistor T1 will also be comprehensively referred to as a “transistor T”.

For example, structures of the transistors T and the storage capacitor Cst and/or a position of each layer thereof are not limited to the embodiments shown in FIG. 13 to FIG. 15, and may be variously changed according to embodiments. In an embodiment, the transistors T included in each pixel circuit PXC may have substantially the same or similar structure to each other, but embodiments are not limited thereto. In another example, at least one of the transistors T included in the pixel circuit PXC may have a different cross-sectional structure from the remaining other transistors T, and/or may be disposed at a different position in a cross-section view.

Referring to FIG. 13 to FIG. 15, the pixels PXL and the display device including the same according to the embodiment may include a circuit layer PCL and a light emitting element layer DPL disposed on the circuit layer PCL.

The circuit layer PCL may include the substrate SUB. The substrate SUB may be a rigid substrate or a flexible substrate, and the material or physical properties of the substrate SUB are not limited. For example, the substrate SUB may be a rigid substrate made of glass or tempered glass, or a flexible substrate made of a thin film made of plastic or metal. For example, the substrate SUB may be a transparent substrate, but embodiments are not limited thereto.

A buffer layer BFL may be disposed on the substrate SUB. The buffer layer BFL may function to smooth a surface of the substrate SUB and prevent penetration or permeation of moisture or external air. The buffer layer BFL may be an inorganic film formed of a single layer or a multilayer.

Various circuit elements such as the transistors T and the storage capacitor Cst, and various wires connected to the circuit elements may be disposed on the buffer layer BFL. In some embodiments, the buffer layer BFL may be omitted, and at least one circuit element and/or wire may be disposed (e.g., directly disposed) on a surface of the substrate SUB.

Each transistor T may include a semiconductor pattern SCL (referred to as a “semiconductor layer” or “active layer”), a gate electrode GE, and first and second transistor electrodes TE1 and TE2. FIG. 13 to FIG. 15 illustrate the embodiment in which each transistor T includes the first and second transistor electrodes TE1 and TE2 formed separately from the semiconductor pattern SCL, but embodiments are not limited thereto. In another example, the first and/or second transistor electrodes TE1 and/or TE2 provided in at least one transistor T may be integral with each semiconductor pattern SCL.

The semiconductor pattern SCL may be disposed on the buffer layer BFL. For example, the semiconductor pattern SCL may be disposed between the substrate SUB on which the buffer layer BFL is formed and a gate insulating layer GI. The semiconductor pattern SCL may include a first area contacting each first transistor electrode TE1, a second area contacting each second transistor electrode TE2, and a channel area disposed between the first and second areas. In some embodiments, one of the first and second areas may be a source area, and the other thereof may be a drain area.

In some embodiments, the semiconductor pattern SCL may be a semiconductor pattern made of polysilicon, amorphous silicon, an oxide semiconductor, or the like. For example, the channel area of the semiconductor pattern SCL may be an intrinsic semiconductor as a semiconductor pattern that is not doped with impurities, and each of the first and second areas of the semiconductor pattern SCL may be a semiconductor pattern doped with impurities.

In an embodiment, the semiconductor patterns SCL of the transistors T included in each pixel circuit PXC may be made of substantially the same or similar material. For example, the semiconductor pattern SCL of the transistors T may be made of a material of polysilicon, amorphous silicon, and an oxide semiconductor. In another example, some of the transistors T and the remaining some thereof may include the semiconductor patterns SCL made of different materials. For example, the semiconductor pattern SCL of some of the transistors T may be made of polysilicon or amorphous silicon, and the semiconductor pattern SCL of other some of the transistors T may be made of an oxide semiconductor.

The gate insulating layer GI may be disposed on the semiconductor pattern SCL. The gate insulating layer GI may be formed as a single layer or a multilayer, and may include at least one inorganic insulating material and/or organic insulating material. For example, the gate insulating layer GI may include a silicon oxynitride (SiON), a silicon nitride (SiNₓ), or a silicon oxide (SiOₓ), and various types of organic/inorganic insulating materials.

The gate electrode GE may be disposed on the gate insulating layer GI. FIG. 13 to FIG. 15 illustrate a top-gate structure of transistor T. However, in another example, the transistor T may have a bottom-gate structure. For example, the gate electrode GE may overlap the semiconductor pattern SCL under the semiconductor pattern SCL.

A first interlayer insulating layer ILD1 may be disposed on the gate electrode GE. For example, the first interlayer insulating layer ILD1 may be disposed between the gate electrode GE and the first and second transistor electrodes TE1 and TE2. The first interlayer insulating layer ILD1 may be formed as a single layer or a multilayer, and may include at least one inorganic insulating material and/or organic insulating material. For example, the first interlayer insulating layer ILD1 may include a silicon oxynitride (SiON), a silicon nitride (SiNₓ), or a silicon oxide (SiOₓ), and various types of organic/inorganic insulating materials, and the materials included in the first interlayer insulating layer ILD1 are not limited.

At least one transistor T provided in the pixel circuit PXC may be connected to at least one pixel electrode ETL1 or ETL2. For example, the first transistor T1 shown in FIG. 6 and the like may be electrically connected to the first electrode ETL1 of the corresponding pixel PXL through a contact hole (for example, the first contact hole CH1) and/or a bridge pattern BRP passing through a passivation layer PSV.

The storage capacitor Cst may include a first capacitor electrode Cst_E1 and a second capacitor electrode Cst_E2 overlapping each other. Each of the first and second capacitor electrodes Cst_E1 and Cst_E2 may be formed of a single layer or a multilayer. For example, at least one of the first and second capacitor electrodes Cst_E1 and Cst_E2 may be disposed on the same layer as at least one electrode or the semiconductor pattern SCL forming the first transistor T1.

For example, the first capacitor electrode Cst_E1 may be formed as a multilayer electrode that includes a lower electrode LE disposed on the same layer as the semiconductor pattern SCL of the first transistor T1, and an upper electrode UE disposed on the same layer as the first and second transistor electrodes TE1 and TE2 of the first transistor T1 and electrically connected to the lower electrode LE. For example, the second capacitor electrode Cst_E2 may be formed as a single layer electrode that is disposed on the same layer as the gate electrode of the first transistor T1 and is disposed between the lower electrode LE and the upper electrode UE of the first capacitor electrode Cst_E1.

However, the structure and/or position of each of the first and second capacitor electrodes Cst_E1 and Cst_E2 may be variously changed. In another example, one of the first and second capacitor electrodes Cst_E1 and Cst_E2 may include a conductive pattern disposed on a layer different from the electrodes (for example, the gate electrode GE, and the first and second transistor electrodes TE1 and TE2) and the semiconductor pattern SCL that form the first transistor T1. For example, the first capacitor electrode Cst_E1 or the second capacitor electrode Cst_E2 may have a single-layered structure or a multi-layered structure including a conductive pattern disposed on a second interlayer insulating layer ILD2.

In an embodiment, at least one signal wire and/or power wire connected to each pixel PXL may be disposed on the same layer as an electrode of circuit elements included in the pixel circuit PXC. For example, the scan line Si of each pixel PXL may be disposed on the same layer as the gate electrodes GE of transistors T, and the data line Dj of each pixel PXL may be disposed on the same layer as the first and second transistor electrodes TE1 and TE2 of transistors T.

The first and/or second power wires PL1 and/or PL2 may be dispose on the same layer as or different layers from the gate electrodes GE or first and second transistor electrodes TE1 and TE2 of the transistors T. For example, the second power wire PL2 for supplying the second power source VSS may be disposed on the second interlayer insulating layer ILD2 to be at least partially covered by the passivation layer PSV. The second power wire PL2 may be connected (e.g., electrically connected) to the second electrode ETL2 of the light source unit LSU disposed on the passivation layer PSV through the second contact hole CH2 passing through the passivation layer PSV. However, the position and/or structure of the first and/or second power wires PL1 and PL2 may be variously changed. In another example, the second power line PL2 may be disposed on the same layer as the gate electrodes GE of the transistors T or the first and second transistor electrodes TE1 and TE2 to be electrically connected to the second electrode ETL2 through at least one bridge pattern and/or the second contact hole CH2.

The second interlayer insulating layer ILD2 may be disposed at an upper portion of the first interlayer insulating layer ILD1, and may cover the first and second transistor electrodes TE1 and TE2 and/or storage capacitor Cst disposed on the first interlayer insulating layer ILD1. The second interlayer insulating layer ILD2 may be formed as a single layer or a multilayer, and may include at least one inorganic insulating material and/or organic insulating material. For example, the second interlayer insulating layer ILD2 may include a silicon oxynitride (SiON), a silicon nitride (SiNx), or a silicon oxide (SiOₓ), and various types of organic/inorganic insulating materials, and the materials included in the second interlayer insulating layer ILD2 are not limited. The bridge pattern BRP, the first power wire PL1, and/or the second Power wire PL2 for connecting at least one circuit element (for example, the first transistor T1) provided in the pixel circuit PXC to the first electrode ETL1 may be disposed on the second interlayer insulating layer ILD2.

However, in some embodiments, the second interlayer insulating layer ILD2 may be omitted. For example, the bridge pattern BRP of FIG. 15 may be omitted, and the second power wire PL2 may be disposed on a layer in which an electrode of the transistor T is disposed.

The passivation layer PSV may be disposed on the circuit elements including the transistors T and the storage capacitor Cst, and/or on the wires including the first and second power wires PL1 and PL2. The passivation layer PSV may be formed as a single layer or a multilayer, and may include at least one inorganic insulating material and/or organic insulating material. For example, the passivation layer PSV may include at least one organic insulating layer, and may substantially flatten a surface of the circuit layer PCL. The light emitting element layer DPL may be disposed on the passivation layer PSV.

The light emitting element layer DPL may include the electrodes ETL1 and ETL2 forming the light source unit LSU of each pixel PXL, the light emitting elements LD, and an insulating reflective layer RFL. For example, the light emitting element layer DPL may further selectively include the first and second contact electrodes CE1 and CE2 for more stably connecting the light emitting elements LD between the first and second electrodes ETL1 and ETL2, the first bank BNK1 for protruding an area of each of the first and second electrodes ETL1 and ETL2 upward, and/or the second bank BNK2 surrounding each light emitting area EMA.

The first bank BNK1 may be disposed on the passivation layer PSV of the circuit layer PCL. The first bank BNK1 may be formed in a separate or integral pattern. The first bank BNK1 may protrude in the third direction (e.g., Z-axis direction) on a surface of the substrate SUB on which the circuit layer PCL is formed.

The first bank BNK1 may have various shapes according to embodiments. In an embodiment, the first bank BNK1 may have an inclined surface inclined at an angle of a range with respect to the substrate SUB. In another example, the first bank BNK1 may have a cross-section of a semicircle or semi-ellipse shape, but embodiments are not limited thereto.

The first bank BNK1 may include an insulating material including at least one inorganic material and/or an organic material. For example, the first bank BNK1 may include at least one layer of inorganic film that includes various inorganic insulating materials including a silicon oxynitride (SiON), a silicon nitride (SiNₓ), or a silicon oxide (SiOₓ). In another example, the first bank BNK1 may include at least one layer of organic film and/or photo resist film that include various organic insulating materials, or may include a single-layered insulator or a multi-layered insulator complexly including organic/inorganic materials. For example, the material and/or pattern shape of the first bank BNK1 may be variously changed.

In an embodiment, the first bank BNK1 may function as a reflective member. For example, the first bank BNK1, with the first and second electrodes ETL1 and ETL2 provided thereon, may function as a reflective member that guides the light emitted from each light emitting element LD in a desired direction (for example, the third direction or Z-axis direction) to improve the light output efficiency of the pixel PXL. In some embodiments, the first bank BNK1 may be omitted.

The first and second electrodes ETL1 and ETL2 included in the pixel electrodes of each pixel PXL may be disposed at the upper portion of the first bank BNK1. In some embodiments, the first and second electrodes ETL1 and ETL2 may have a shape corresponding to the first bank BNK1. For example, the first and second electrodes ETL1 and ETL2 may have respective inclined or curved surfaces corresponding to the first bank BNK1, and may protrude in the third direction (e.g., Z-axis direction). In case that the first bank BNK1 is not formed, the first and second electrodes ETL1 and ETL2 may be substantially formed flat on the passivation layer PSV or have different thicknesses for each area, so that an area may protrude in the third direction (e.g., Z-axis direction) of the substrate SUB.

Each of the first and second electrodes ETL1 and ETL2 may include at least one conductive material. For example, each of the first and second electrodes ETL1 and ETL2 may include at least one metal of various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), and copper (Cu), or an alloy including the same; a conductive oxide such as an indium tin oxide (ITO), an indium zinc oxide (IZO), an indium gallium zinc oxide (IGZO), an indium tin zinc Oxide (ITZO), a zinc oxide (ZnO), an aluminum doped zinc oxide (AZO), a gallium doped zinc oxide (GZO), a zinc tin oxide (ZTO), a gallium tin oxide (GTO), and a fluorine doped tin oxide (FTO); and at least one conductive material among conductive polymers such as PEDOT, but embodiments are not limited thereto. For example, each of the first and second electrodes ETL1 and ETL2 may include other conductive materials in addition to a carbon nanotube or graphene. For example, each of the first and second electrodes ETL1 and ETL2 may have conductivity by including at least one of various conductive materials, but the materials included therein are not limited. For example, the first and second electrodes ETL1 and ETL2 may include the same conductive material, or may include different conductive materials.

The insulating reflective layer RFL may be disposed on an area of the first and second electrodes ETL1 and ETL2. The insulating reflective layer RFL may overlap the light emitting element LD in the third direction (e.g., Z-axis direction). The insulating reflective layer RFL may be disposed (e.g., directly disposed) on the first electrode ETL1 and the second electrode ETL2, and the light emitting element LD may be disposed (e.g., directly disposed) on the insulating reflective layer RFL. For example, a surface (e.g., a first surface) of the insulating reflective layer RFL may be in contact with the first electrode ETL1 and the second electrode ETL2, and another surface (e.g., a second surface) of the insulating reflective layer RFL may be in contact with the light emitting element LD. For example, the insulating reflective layer RFL may overlap the first end portion EP1 and the second end portion EP2 of the light emitting element LD. Accordingly, the light emitted from the first end portion EP1 and the second end portion EP2 of the light emitting element LD may be reflected by the insulating reflective layer RFL disposed therebelow to be emitted in the front direction of the display panel PNL, e.g., in the third direction (e.g., Z-axis direction). Accordingly, an amount of light lost to a lower portion of the display panel PNL may be minimized, so that the light output efficiency may be improved.

For example, the insulating reflective layer RFL may have a thickness TH in the third direction (e.g., Z-axis direction). For example, the thickness TH of the insulating reflective layer RFL may include a first thickness TH1 between an upper surface of the passivation layer PSV and a lower surface of the light emitting elements LD and a second thickness TH2 between an upper surface of the first electrode ETL1 (or the second electrode ETL2) and a lower surface of the first contact electrode CE1 (or the second contact electrode CE2). For example, the insulating reflective layer RFL may include a first insulating reflective portion having the first thickness TH1 and a second insulating reflective portion having the second thickness TH2 smaller than the first thickness TH1. For example, the first insulating reflective portion may be adjacent to sides of the first and second electrodes ETL1 and ETL2 and may be in contact with the passivation layer PSV. For example, the first insulating reflective portion may overlap a center portion of the the light emitting element LD, and the second insulating reflective portion may overlap the first end portion EP1 and the second end portion EP2 of the light emitting element LD.

The insulating reflective layer RFL may be disposed between the first and second electrodes ETL1 and ETL2 and the first and second contact electrodes CE1 and CE2. The insulating reflective layer RFL may cover an area of each of the first electrode ETL1 and the second electrode ETL2, and may include an opening exposing another area of each of the first electrode ETL1 and the second electrode ETL2. For example, the insulating reflective layer RFL may expose an area of the first electrode ETL1 and the second electrode ETL2 on each of the first banks BNK1. The first and second electrodes ETL1 and ETL2 may be connected (e.g., electrically connected) to the first and second contact electrodes CE1 and CE2 through the opening of the insulating reflective layer RFL.

In an embodiment, the insulating reflective layer RFL may cover (e.g., entirely cover) the first electrode ETL1 and the second electrode ETL2. After the light emitting elements LD are supplied and aligned on the insulating reflective layer RFL, the insulating reflective layer RFL may be opened (e.g., partially opened) to expose an area of each of the electrodes ETL1 and ETL2 in an area on each first bank BNK1. In another example, the insulating reflective layer RFL may be patterned in a form of an individual pattern that is locally disposed only under the light emitting elements LD after the light emitting elements LD are completely supplied and arranged. After the first electrode ETL1 and the second electrode ETL2 are formed, the insulating reflective layer RFL may cover the first electrode ETL1 and the second electrode ETL2 to prevent the first electrode ETL1 and the second electrode ETL2 from being damaged in a subsequent process. For example, the insulating reflective layer RFL may function to stably support each light emitting element LD. Accordingly, since a separate insulating layer disposed between the light emitting element LD and the first electrode ETL1 and the second electrode ETL2 is omitted, the manufacturing process of the display device may be simplified.

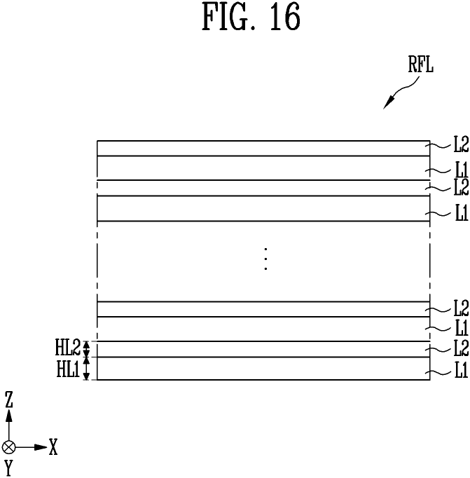

The insulating reflective layer RFL may include a reflective material having insulating properties. As the insulating reflective layer RFL excludes a conductive material, the insulating reflective layer RFL may not affect or influence the alignment of the light emitting element LD. The insulating reflective layer RFL may include at least one of a barium sulfate (BaSO₄), a titanium oxide (TiO₂), a silicon oxide (SiO₂), a zinc oxide (ZnO), a lead carbonate (PbCO₃), and an aluminum oxide (Al₂O₃) as a reflective material. However, embodiments are not limited thereto, and various reflective materials may be selected within a range that ensures reflectance. In an embodiment, the insulating reflective layer RFL may be implemented as a distributed Bragg reflector (DBR). This will be described in detail with reference to FIG. 16.

FIG. 16 illustrates a schematic cross-sectional view of an insulating reflective layer according to an embodiment.

Referring to FIG. 16, the insulating reflective layer RFL may include first layers L1 and second layers L2 having different refractive indexes. The first layers L1 and second layers L2 may be alternately stacked.

The first layer L1 and the second layer L2 may include inorganic materials having different refractive indexes. For example, each of the first layer L1 and the second layer L2 may include at least one of a silicon oxide (SiOₓ), a silicon nitride (SiNₓ), a silicon oxynitride (SiOₓN_{y}), a silicon oxycarbide (SiOₓC_{y}), a silicon carbonitride (SiCₓN_{y}), a silicon oxycarbide (SiOₓC_{y}), an aluminum oxide (AlOₓ), an aluminum nitride (AlNₓ), a hafnium oxide (HfOₓ), a zirconium oxide (ZrOₓ), a titanium oxide (TiOₓ), and a tantalum oxide (TaOₓ).

The first layer L1 and the second layer L2 may have different thicknesses. For example, the thickness of each of the layers may be a thickness in the third direction (e.g., Z-axis direction). A thickness HL1 of the first layer L1 and a thickness HL2 of the second layer L2 may be adjusted according to a wavelength of light emitted by the light emitting element LD, respectively. For example, the thickness HL1 of the first layer L1 and the thickness HL2 of the second layer L2 may be adjusted to satisfy Equation 1 and Equation 2, respectively.

$$H L 1 = \frac{m \text{λ}}{4 \text{n1cos} θ} \qquad \text{(Equation 1)}$$

$$H L 2 = \frac{m \text{λ}}{4 \text{n2} c o s θ} \qquad \text{(Equation 2)}$$

In Equation 1 and Equation 2, HL1 and HL2 are thicknesses of the first layer L1 and the second layer L2, respectively, m is a natural number that is selected by a designer in consideration of process capability and the like, λ is a reflective wavelength of the insulating reflective layer RFL or a wavelength of light emitted by the light emitting element LD, n1 and n2 are refractive indexes of the first layer L1 and the second layer L2, respectively, and θ is an angle of incidence to the insulating reflective layer RFL.

In an embodiment, the first layer L1 may include a silicon oxide (SiOₓ), and the second layer L2 may include a silicon nitride (SiNₓ). For example, the refractive index of the first layer L1 may be smaller than the refractive index of the second layer L2, and the thickness HL1 of the first layer L1 may be greater than the thickness HL2 of the second layer L2. For example, the first layer L1 may include a silicon oxide (SiOₓ), and the second layer L2 may include a titanium oxide (TiOₓ). For example, the refractive index of the first layer L1 may be smaller than the refractive index of the second layer L2, and the thickness HL1 of the first layer L1 may be greater than the thickness HL2 of the second layer L2.

The insulating reflective layer RFL may include 4 to 10 pairs of the first layers L1 and the second layers L2, respectively, according to materials forming the first layer L1 and the second layer L2.

Hereinafter, reflectance and light output efficiency for a comparative example and an example will be described with reference to Table 1. The comparative example is a case in which the pixel PXL does not include an insulating reflective layer, and Examples 1 to 3 are cases in which the pixel PXL includes the insulating reflective layer RFL. For example, Example 1 is a case in which the first layer L1 includes a silicon oxide (SiOₓ) and the second layer L2 includes a silicon nitride (SiNₓ), and that includes three pairs of the first layers L1 and the second layers L2. Example 2 is a case in which the first layer L1 includes a silicon oxide (SiOₓ) and the second layer L2 includes a silicon nitride (SiNₓ), and that includes four pairs of the first layers L1 and the second layers L2. Example 3 is a case in which the first layer L1 includes a silicon oxide (SiOₓ), the second layer L2 includes a titanium oxide (TiOₓ), and four pairs of the first layers L1 and the second layers L2 are stacked.

TABLE 1

| | First layer L1 | Second layer L2 | Pair | Thickness of insulating reflective layer RFL (Å) | Reflectance (%) | Light output efficiency (%) |
|---|---|---|---|---|---|---|
| Comparative example | SiO_{X} | SiO_{X} | - | 3,000 | 4.4 | 29.11 |
| Example 1 | SiO_{X} | SiNₓ | 3 | 3,660 | 30.7 | 29.43 |
| Example 2 | SiO_{X} | SiNₓ | 4 | 5,200 | 45.9 | 34.54 |
| Example 3 | SiO_{X} | TiOₓ | 4 | 4,800 | 78.3 | 35.38 |

The reflectance is measured at about 446 nm as a reference, respectively. the comparative example has a reflectance of about 4.4 %. Example 1 has a reflectance of about 30.7 %. Example 2 has a reflectance of about 45.9%. Example 3 has a reflectance of about 78.9%. Accordingly, the light output efficiency of Example 1 is about 29.43 %, which is improved by about 1 % compared to the comparative example. The light output efficiency of Example 2 is about 34.54 %, which is improved by about 18 % compared to the comparative example. The light output efficiency of Example 3 is about 35.38 %, which is improved by about 21 % compared to the comparative example. Therefore, in case that four pairs of the first layers L1 and the second layers L2 are included according to Example 2 and Example 3, the reflectance of the insulating reflective layer RFL may be ensured, and thus the light output efficiency of the display device may be improved. As a result, the thickness TH of the insulating reflective layer RFL may be about 4,000 angstroms or more, and the insulating reflective layer RFL may include four or more pairs of the first layers L1 and the second layers L2. Referring back to FIG. 13 to FIG. 15, light emitting elements LD may be supplied and aligned on the insulating reflective layer RFL. For example, before the light emitting elements LD is supplied, the second bank BNK2 may be formed around the light emitting area EMA. For example, the second bank BNK2 may surround each light emitting area EMA.

The light emitting elements LD may be supplied to each pixel area PXA in which the first bank BNK1, the first and second electrodes ETL1 and ETL2, the second bank BNK2, and the like are arranged between the first and second electrodes ETL1 and ETL2. For example, light emitting elements LD may be supplied to the light emitting area EMA of each pixel PXL through an inkjet method, a slit coating method, or various other methods, and the light emitting elements LD may be aligned between the first and second electrodes ETL1 and ETL2 with directionality by an alignment signal (or alignment voltage) applied to each of the first and second electrodes ETL1 and ETL2.

The insulating pattern INP may be disposed on an area of the light emitting elements LD. For example, the insulating pattern INP may be disposed on an area of each of the light emitting elements LD to expose the first and second end portions EP1 and EP2 of each of the light emitting elements LD. For example, the insulating pattern INP may be locally disposed only at an upper portion of an area including a central area of each of the light emitting elements LD.

The insulating pattern INP may be formed in an independent pattern in the light emitting area EMA of each pixel PXL, but embodiments are not limited thereto. In some embodiments, the insulating pattern INP may be omitted.

The insulating pattern INP may be formed as a single layer or a multilayer, and may include at least one inorganic insulating material and/or organic insulating material. For example, the insulating pattern INP may include a silicon nitride (SiNₓ), a silicon oxide (SiOₓ), an aluminum oxide (Al₂O₃), a photo resist, and various types of organic/inorganic insulating materials. In case that the insulating pattern INP is formed on the light emitting elements LD after the alignment of the light emitting elements LD is completed, the light emitting elements LD may not be deviated from an aligned position.

End portions (e.g., opposite end portions) of the light emitting elements LD that are not covered by the insulating pattern INP, e.g., the first and second end portions EP1 and EP2, may be covered by the first and second contact electrodes CE1 and CE2, respectively. The first and second contact electrodes CE2 and CE2 may be spaced apart from each other. For example, the adjacent first and second contact electrodes CE1 and CE2 may be spaced apart from each other on the first and second end portions EP1 and EP2 of at least one adjacent the light emitting element LD, with the insulating pattern INP therebetween.

For example, the first and second contact electrodes CE1 and CE2 may be disposed at the upper portion of the first and second electrodes ETL1 and ETL2 to cover the exposed area of each of the first and second electrodes ETL1 and ETL2. For example, the first and second contact electrodes CE1 and CE2 may be disposed on at least a portion of each of the first and second electrodes ETL1 and ETL2 so as to be in contact with each of the first and second electrodes ETL1 and ETL2 at the upper portion of the first bank BNK1 or around the first bank BNK1. Accordingly, the first and second contact electrodes CE1 and CE2 may be connected (e.g., electrically connected) to the first and second electrodes ETL1 and ETL2, respectively. For example, through the first and second contact electrodes CE1 and CE2, the first and second electrodes ETL1 and ETL2 may be electrically connected to the first and second end portions EP1 and EP2 of at least one light emitting element LD adjacent thereto, respectively.

In an embodiment, as shown in FIG. 13, the first and second contact electrodes CE1 and CE2 may be simultaneously formed on the same layer on a surface of the substrate SUB. Accordingly, a manufacturing process of the pixel PXL and the display device including the same may be simplified. However, embodiments are not limited thereto, and the position and mutual arrangement relationship of the first and second contact electrodes CE1 and CE2 may be variously changed. For example, the first and second contact electrodes CE1 and CE2 may be sequentially formed on different layers on a surface of the substrate SUB as shown in FIG. 14. For example, the second insulating layer INS2 may be additionally disposed between the first contact electrode CE1 and the second contact electrode CE2. For example, the position and mutual arrangement relationship of the contact electrodes CE1 and CE2 may be variously changed.

In some embodiments, the contact electrodes CE1 and CE2 may be made of various transparent conductive materials. For example, the contact electrodes CE1 and CE2 may include at least one of various transparent conductive materials in addition to ITO, IZO, ZnO, IGZO, and ITZO, and may be implemented to be substantially transparent or transflective to satisfy a light transmittance. Accordingly, the light emitted from the light emitting elements LD through the first end portion EP1 and the second end portion EP2 may pass through the contact electrodes CE1 and CE2 to be emitted to the outside of the display device.

A first insulating layer INS1 may be disposed on the contact electrodes CE1 and CE2. For example, the first insulating layer INS1 may be formed (e.g., entirely formed) on the substrate SUB to cover the first and second electrodes ETL1 and ETL2, the light emitting elements LD, the insulating pattern INP, and the first and second contact electrodes CE1 and CE2. The first insulating layer INS1 may include at least one layer of an inorganic layer and/or organic layer. In some embodiments, the first insulating layer INS1 may include a thin film encapsulation layer of a multi-layered structure. For example, the first insulating layer INS1 may include a thin film encapsulation layer of a multi-layered structure that includes at least two inorganic insulating layers and at least one organic insulating layer disposed between the at least two inorganic insulating layers. However, embodiments are not limited thereto, and the material and/or structure of the first insulating layer INS1 may be variously changed.

In some embodiments, at least one overcoat layer OC may be further disposed on the first insulating layer INS1. The overcoat layer OC may be formed as a single layer or a multilayer, and may include at least one inorganic insulating material and/or organic insulating material. For example, each of the overcoat layers OC may include various types of organic/inorganic insulating materials.

According to the display device according to the above-described embodiment, the light emitted from the first end portion EP1 and the second end portion EP2 of the light emitting element LD may be reflected by the insulating reflective layer RFL under the light emitting element LD to be emitted in the front direction of the display panel PNL (e.g., in the third direction or Z-axis direction. Accordingly, an amount of light lost to a lower portion of the display panel PNL may be minimized, so that the light output efficiency may be improved.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

1. A display device comprising:
a substrate including a plurality of pixels;
a first electrode and a second electrode disposed on the substrate and spaced apart from each other;
an insulating reflective layer disposed on the first electrode and the second electrode; and
a plurality of light emitting elements disposed between the first electrode and the second electrode and electrically connected to the first electrode and the second electrode, wherein
the insulating reflective layer includes a plurality of first layers and a plurality of second layers having different refractive indexes, and
the plurality of first layers and the plurality of second layers are alternately stacked with each other.

2. The display device of claim 1, wherein
the insulating reflective layer overlaps end portions of the plurality of light emitting elements.

3. The display device of claim 1, wherein
a refractive index of the plurality of first layers of the insulating reflective layer is smaller than a refractive index of the plurality of second layers of the insulating reflective layer.

4. The display device of claim 3, wherein
a thickness of each of the plurality of first layers of the insulating reflective layers is greater than a thickness of each of the plurality of second layers of the insulating reflective layer.

5. The display device of claim 4, wherein
a thickness of the insulating reflective layer is about 4,000 angstroms or more.

6. The display device of claim 1, wherein
the insulating reflective layer includes four or more pairs of the plurality of first layers and the plurality of second layers.

7. The display device of claim 6, wherein
each of the plurality of first layers of the insulating reflective layer includes a silicon oxide, and
each of the plurality of second layers of the insulating reflective layer includes a silicon nitride.

8. The display device of claim 6, wherein
each of the plurality of first layers of the insulating reflective layer includes a silicon oxide, and
each of the plurality of second layers of the insulating reflective layer includes a titanium oxide.

9. The display device of claim 1, further comprising;
a first contact electrode contacting the first electrode and an end portion of each of the plurality of light emitting elements; and
a second contact electrode contacting the second electrode and another end portion of each of the plurality of light emitting elements.

10. The display device of claim 9, wherein
the insulating reflective layer is disposed between the first electrode and the first contact electrode.

11. The display device of claim 10, wherein
a surface of the insulating reflective layer contacts the first electrode, and
another surface of the insulating reflective layer contacts the first contact electrode.

12. The display device of claim 10, wherein
the insulating reflective layer includes an opening that partially exposes the first electrode.

13. The display device of claim 12, wherein
the first contact electrode contacts the first electrode through the opening of the insulating reflective layer.

14. A display device comprising:
a substrate including a plurality of pixels;
a first electrode and a second electrode disposed on the substrate and spaced apart from each other;
an insulating reflective layer disposed on the first electrode and the second electrode; and
a plurality of light emitting elements disposed on the insulating reflective layer and electrically connected to the first electrode and the second electrode, wherein
the insulating reflective layer includes a first insulating reflective portion having a first thickness and a second insulating reflective portion having a second thickness smaller than the first thickness.

15. The display device of claim 14, wherein
the first insulating reflective portion overlaps a center portion of each of the plurality of light emitting elements, and
the second insulating reflective portion overlaps an end portion of each of the plurality of light emitting elements.

16. The display device of claim 14, wherein the first insulating reflective portion is adjacent to a side of the first electrode and a side of the second electrode.

17. The display device of claim 14, wherein
the insulating reflective layer includes a plurality of first layers and a plurality of second layers having different refractive indexes, and
the plurality of first layers and the plurality of second layers are alternately stacked with each other.

18. The display device of claim 17, wherein a refractive index of the plurality of first layers of the insulating reflective layer is smaller than a refractive index of the plurality of second layers of the insulating reflective layer.

19. The display device of claim 18, wherein a thickness of each of the plurality of first layers of the insulating reflective layer is greater than a thickness of each of the plurality of second layers of the insulating reflective layer.

20. The display device of claim 17, wherein the insulating reflective layer includes four or more pairs of the plurality of first layers and the plurality of second layers.
